(19) United States
(12) Patent Application Publication
(10) Pub. No.: US 2005/0176237 A1
(43) Pub. Date: Aug. 11, 2005

(54) In-situ liner formation during reactive ion etch

(76) Inventors: Theodorus E. Standaert, Pine Bush, NY (US); Bernd E. Kastenmeier, Austin, TX (US); Yi-Hsiung Lin, Wappingers Falls, NY (US); Yi-Fang Cheng, Chu-tong (TW); Larry Clevenger, LaGrangeville, NY (US); Stephen Greco, LaGrangeville, NY (US); O Sung Kwon, Dresden (DE)

Correspondence Address: Jackson Walker LLP, Ste. 600, 2435 N. Central Expwy, Richardson, TX, 75080, US

(21) Appl. No.: 10/772,777

(22) Filed: Feb. 5, 2004

(51) Int. Cl. H01L 21/4763

(52) U.S. Cl. 438/623; 438/639; 438/622; 438/627; 438/643

(57) ABSTRACT

In damascene processing, metal hardmask sputtering redeposition that occurs during reactive ion etching (RIE) is exploited to produce, during the RIE process, a desired barrier metal liner on the etched feature.

### FIELD OF THE INVENTION

The invention relates generally to semiconductor integrated circuit manufacturing and, more particularly, to in-situ liner formation during reactive ion etching (“RIE”).

### BACKGROUND OF THE INVENTION

As wafer fabrication design rules reduce to 0.15 μm linewidths and below, the increased packing density of devices on a chip permits more electrical signal speed from device to device. This density leads to improved chip performance. However, this improved chip performance is only possible if the interconnect system between the devices is optimized. Narrower linewidths lead to increased line resistance. Tightly spaced conductor lines with a dielectric material between them act as capacitors, leading to a degradation in performance from an increased resistance (“R”) and capacitance (“C”). If either or both of these parameters are reduced, then the signal delay reduces, leading to increased chip performance. One method for reducing interconnect resistance is to increase the conductor cross section. However, this contradicts the goal of increased packing density since wider conductors will require more space. Additionally, smaller integrated circuit (“IC”) feature sizes are not achievable with larger linewidths. This has lead the semiconductor industry to search for alternative materials and processes.

Conventionally, aluminum (“Al”) has been used by the semiconductor industry as an interconnect material. Recently, copper (“Cu”) has been introduced as an interconnect material. The use of copper metallization provides improved performance and reliability over aluminum. Copper can lower the interconnect resistance, lowering R and the overall signal delay. Additionally, copper enables the creation of smaller linewidths with the ability to carry the same amount of current as large linewidths, permitting a tighter packing density on each metal level The optimum improvement to RC signal delay is gained when R is reduced and C is lowered by using a low-k dielectric, along with thinner barrier metals.

However, semiconductor processing with copper metallurgy can be complicated, for a number of reasons. One, copper diffuses quickly into oxides and silicon. Therefore, copper must be isolated from the surrounding inter-level dielectric (“ILD”). If the copper reaches the silicon substrate, it will significantly degrade device performance. Additionally, copper cannot be easily patterned using regular plasma etching techniques. Copper dry etching does not produce a necessary volatile by-product during the chemical reaction as required for economical dry etching. Furthermore, copper oxidizes quickly in air at low temperatures (i.e., <200° C.) and does not form a protective layer to stop further oxidation. Therefore, to form copper interconnect wiring, damascene processing has been introduced. Damascene processing eliminates the need to etch copper because a dielectric etch is used to define the critical line width and spacing, rather than the metal etch used with aluminum.

In a damascene process, both the vias and lines for each metal layer are created by etching holes and trenches in the ILD, depositing copper in the etched features and using CMP to remove excess copper. Damascene processing may include trench-first, via-first, and self-aligned etching. FIG. 1 illustrates a known example of a damascene process. In step 105, an ILD oxide (e.g., a low-k material) is deposited on a wafer using, for example, plasma-enhanced chemical vapor deposition (“PECVD”). Next, in step 110, one or more dielectric capping/hardmask layers are deposited on the ILD. In step 115, a metal hardmask is deposited next. Feature (e.g., line or via) lithography is performed in step 120, resulting in the structure of FIG. 2. In step 125, the feature is etched into the metal hardmask deposited in step 115 and, possibly, into one of the dielectric hardmask layers deposited in step 110, resulting in the structure of FIGS. 3 (with photoresist) and 4 (photoresist removed). In step 135, the ILD is etched by RIE.

During the RIE step 135, the sputter rate associated with the metal hardmask is finite but non-zero. In a dielectric etch chamber, sputter products from the metal hardmask can be expected to be involatile and will therefore stick to most surfaces. So, when the metal hardmask is exposed to the plasma during the RIE process, some redeposition of sputtered metallic products from the metal hardmask can be expected to occur inside the partially etched feature.

After RIE, in step 140, a diffusion layer of barrier metal (e.g., tantalum and tantalum nitride) is deposited on the bottom and sidewalls of the trenches and vias. If the aforementioned sputtering and redeposition of the metal hardmask occurs during RIE, then it is typically necessary to remove the redeposition products from the etched feature (e.g., from the sidewalls and/or bottom of a trench) before the barrier deposition 140. A copper seed layer is deposited onto the barrier metal in step 145. Copper is then used to fill both the vias and trenches in step 150. Finally, in step 155, excess copper is removed through surface planarization, such as CMP. The resulting surface is a planar structure with copper inlays forming the circuitry in the dielectric.

Because copper has high diffusity in silicon and silicon dioxide, which can destroy device performance, the aforementioned layer of barrier metal can be critical for copper metallurgy. Copper typically requires complete encapsulation by a thin-film barrier layer that functions as an adhesion promoter and as an effective diffusion barrier. For copper interconnect metallurgy, tantalum (“Ta”), tantalum nitride (“TaN”), and tantalum silicon nitride (“TaSiN”) have been implemented as barrier metals. Heretofore, barrier metals have been deposited in a separate chamber as a separate processing step (Step 140, FIG. 1) after RIE (Step 135, FIG. 1). This subjects the low-k dielectric to an air break exposure, which can result in damage due to moisture uptake.

It is therefore desirable to provide a solution that reduces the possibility of damage to low-k dielectrics caused by exposure to air during damascene processing. Exemplary embodiments of the present invention exploit metal hardmask sputtering redeposition that occurs during RIE, thereby to produce the desired barrier layer during RIE while also avoiding air break exposure of the low-k dielectric.

### BRIEF DESCRIPTION OF THE DRAWINGS

The above and further advantages of the invention may be better understood by referring to the following description in conjunction with the accompanying drawings in which corresponding numerals in the different figures refer to the corresponding parts, in which:

FIG. 1 illustrates a known damascene process;

FIGS. 2-4 physically illustrate selected operations of FIG. 1;

FIG. 5 illustrates exemplary embodiments of a damascene process in accordance with the present invention; and

FIGS. 6-8 physically illustrate an example of the RIE operation of FIG. 5.

### DETAILED DESCRIPTION

The present invention can reduce the possibility of damage to the low-k dielectrics caused by exposure to air during processing, such as (single or dual) damascene processing. Exemplary embodiments of the present invention can provide this by incorporating the deposition of a barrier layer into an RIE step. As used hereinbelow, the term metal liner or metallic liner refers to a liner that contains, but need not consist exclusively of, metal.

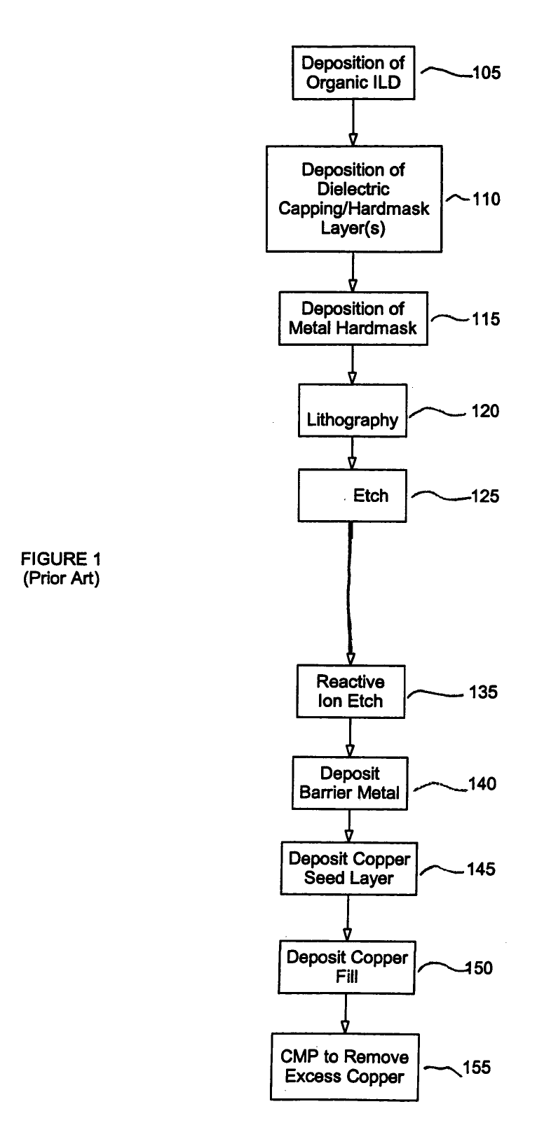

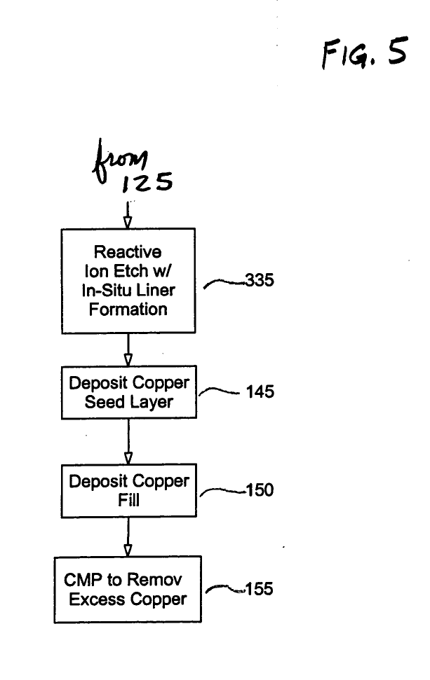

Exemplary embodiments of the present invention modify RIE parameters to form a metallic liner (or barrier layer) during the RIE step of damascene processing (i.e., in-situ) rather than applying the metallic liner as a separate processing step. FIG. 5 illustrates exemplary embodiments of a damascene process in accordance with the present invention. FIG. 5 shows that step 135 of FIG. 1 can be replaced by step 335, which includes RIE with in-situ barrier metal liner formation. Therefore, step 140 of FIG. 1 is not needed, so operations can proceed directly from 335 in FIG. 5 to 145 in FIG. 1.

As mentioned above, during conventional RIE at 135 in FIG. 1, although the selectivity to the metal hardmask is typically high, there is some erosion of the metal hardmask (e.g., by physical sputtering). The products that are formed as a result of the hardmask erosion are most likely non-volatile and will redeposit on any surface. Examples of such surfaces include the etch front and the sidewalls inside the damascene feature. Therefore, while the features are being etched, metallic products can be deposited onto the aforementioned surfaces. Conventional processing attempts to minimize formation of these products because they may lead, for example, to micromasking, sidewall sloping, etch stop and polymerization of the surface. However, according to exemplary embodiments of the invention, by specific selection of the metal hardmask and the RIE discharge parameters (based on the RIE reactor and choice of feedgases), it is possible to produce, within the dielectric etch chamber, a desired RIE profile, while also using the metallic redeposition to produce a conformal metallic liner on both the sidewalls and the bottom of the etched feature. In other words, a metallic liner can be formed during RIE, in the RIE chamber. The metal hardmask is thus used as a sputter target for the liner deposition (which takes place in-situ during RIE).

An exemplary in-situ liner process in accordance with exemplary embodiments of the present invention can include a metal hardmask, for example TaN, as the liner target. In some exemplary embodiments, the addition of a fluorocarbon gas, such as CF₄, in the RIE process can trigger changes to the liner. The pairing of TaN and CF₄ can result in the deposition of a Ta-containing liner along feature sidewalls. By controlling discharge parameters, it is possible to control the sidewall angle of the RIE profile and, thus, the liner angle.

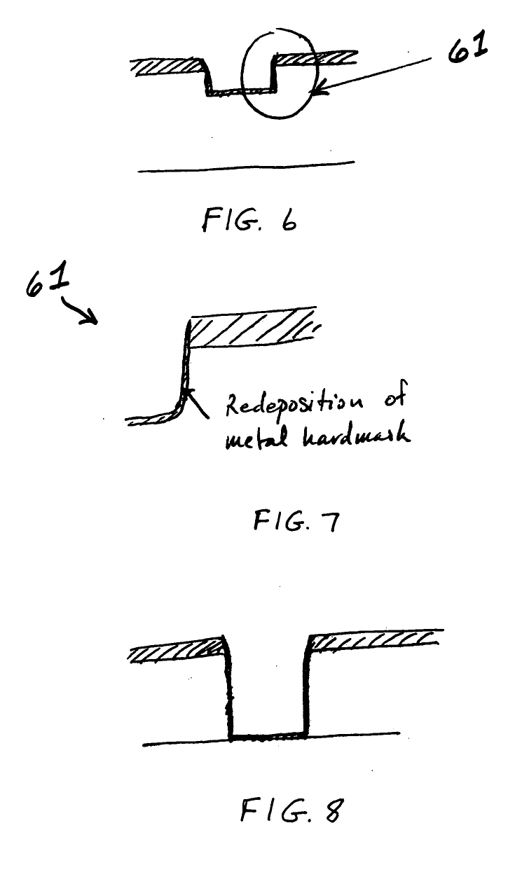

FIGS. 6-8 physically illustrate an example of the RIE operation 335 of FIG. 5. The physical changes illustrated in FIGS. 6-8 begin with the metal hardmask exposed as illustrated in FIG. 4. The beginning of the RIE process is shown in FIG. 6, wherein the process of etching the trench into the dielectric begins. FIG. 7 illustrates the detail portion 61 of FIG. 6, that is, the redeposition of sputtered metallic products from the metal hardmask. FIG. 8 illustrates the completed feature, in this example a trench, with the metal liner produced by the sputtering redeposition of metallic particles from the metal hardmask. As mentioned above, according to exemplary embodiments of the invention, the redeposition is controlled to avoid negative effects such as micromasking and excessive sidewall sloping.

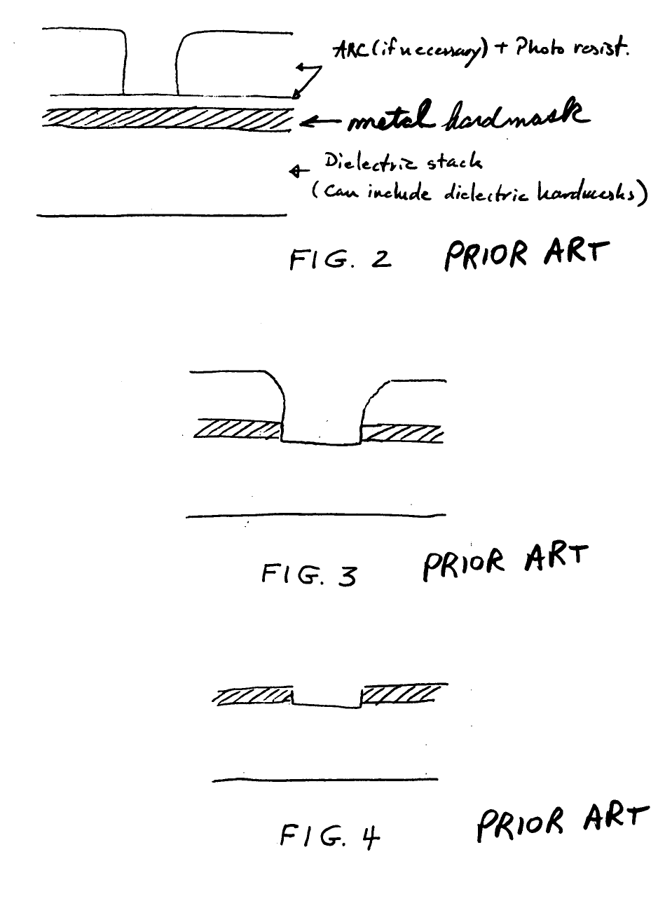

In some exemplary embodiments, the etch process illustrated in FIGS. 5-8 is a two-step etch using a conventionally available etch tool (parallel plate, medium density plasma). The first step is to transfer the pattern of the metal hardmask into the dielectric hardmask underneath (see also FIGS. 1-4). The second step is to etch the pattern into the dielectric. For the first step, the following exemplary parameters can be used with a TEL SCCM etch tool: low pressure in the range of 30 mT-100 mT; total RF power (with some bias power in some embodiments) above approximately 800 watts; mid to high Ar flow rate 350-700 sccm; and aggressive chemistry with CF₄ (e.g., 10-45 sccm) and/or CHF₃ (e.g., 10-45 sccm), and O₂ (e.g., 10-30 sccm). In one example of the second step, again with a TEL SCCM tool, and assuming for this example an organic dielectric (either dense or porous), an etch gas mixture of N₂ (e.g., approximately 300 sccm) and H₂ (e.g., approximately 300 sccm) is used, the 30 mT-100 mT pressure range is used, and the total RF power is maintained at a predetermined level (for example, in a TEL SCCM etch chamber, approximately 2000 watts at 60 MHz and approximately 1000 watts at 2 MHz) in order to have enough energy to sputter some of the metal hardmask to provide the in-situ formation of the metal liner during the RIE process. With the exception of the RIE parameters specified above, the RIE process according to the invention can utilize conventionally known RIE techniques.

In addition to the exemplary advantages described above, by eliminating the need for a separate liner deposition step after etching, in-situ liner deposition reduces turn around time, cost, and other related factors in semiconductor integrated circuit manufacturing.

Although exemplary embodiments of the invention are described above in detail, this does not limit the scope of the invention, which can be practiced in a variety of embodiments. For example, although specific examples of etching an organic dielectric are described above, workers in the art will recognize that the invention is applicable to either organic or inorganic dielectrics, whether dense or porous. Also, although a TEL SCCM etch tool is specified in some examples above, workers in the art will recognize that other etch tools, for example a LAM HPT etch tool, can be used to practice the invention.

1. A method of fabricating a semiconductor integrated circuit, comprising:
providing a dielectric portion;
etching the dielectric portion to produce a feature;
during said etching step, providing on the feature a liner material to produce a lined feature; and
depositing a conductive material on the lined feature.

2. The method of claim 1, wherein said etching step includes reactive ion etching.

3. The method of claim 1, wherein said etching step includes reactive ion etching, wherein said liner is a metallic liner, and wherein said liner providing step includes redepositing sputter products from a metal hardmask during said reactive ion etching step.

4. The method of claim 3, wherein said reactive ion etching step includes using a fluorocarbon gas.

5. The method of claim 4, wherein the fluorocarbon gas is CF₄.

6. The method of claim 3, wherein the metal hardmask is TaN.

7. The method of claim 6, wherein said reactive ion etching step includes using a fluorocarbon gas.

8. The method of claim 1, wherein the dielectric portion includes a low-k dielectric.

9. The method of claim 1, wherein the dielectric portion includes an organic dielectric.

10. The method of claim 1, including providing a seed layer on the liner material before said depositing step.

11. The method of claim 1, wherein said conductive material is copper.

12. The method of claim 1, wherein the feature is one of a trench and a via hole.

13. The method of claim 1, wherein said etching step includes reactive ion etching, said reactive ion etching step including using a TEL SCCM etch tool.

14. The method of claim 1, wherein said etching step includes etching through a dielectric hardmask of the dielectric portion, said step of etching through the dielectric hardmask including using pressure in a range of 30 mT-100 mT, using total RF power above approximately 800 watts, using an Ar flow rate in a range of 350-700 sccm, using an O₂ flow rate in a range of 10-30 sccm, and using one of a CF₄ flow rate in a range of 10-45 sccm and a CHF₃ flow rate in a range of 10-45 sccm.

15. The method of claim 14, wherein said etching step includes etching an organic dielectric of the dielectric portion, said step of etching the organic dielectric including using an etch gas that is a mixture of N₂ at a flow rate of approximately 300 sccm and H₂ at a flow rate of approximately 300 sccm, and using a total RF power of approximately 3000 watts.

16. A semiconductor integrated circuit fabricated according to the method of claim 1.

17. A method of fabricating a semiconductor integrated circuit, comprising:
providing a dielectric portion;
in an etch chamber, etching the dielectric portion to produce a feature;
in said etch chamber, providing on the feature a liner material to produce a lined feature; and
depositing a conductive material on the lined feature.

18. The method of claim 17, wherein said etching step includes reactive ion etching, wherein said liner is a metallic liner, and wherein said liner providing step includes redepositing sputter products from a metal hardmask during said reactive ion etching step.

19. The method of claim 17, wherein said etching step includes etching through a dielectric hardmask of the dielectric portion, said step of etching through the dielectric hardmask including using pressure in a range of 30 mT-100 mT, using total RF power above approximately 800 watts, using an Ar flow rate in a range of 350-700 sccm, using an O₂ flow rate in a range of 10-30 sccm, and using one of a CF₄ flow rate in a range of 10-45 sccm and a CHF₃ flow rate in a range of 10-45 sccm.

20. The method of claim 19, wherein said etching step includes etching an organic dielectric of the dielectric portion, said step of etching the organic dielectric including using an etch gas that is a mixture of N₂ at a flow rate of approximately 300 sccm and H₂ at a flow rate of approximately 300 sccm, and using a total RF power of approximately 3000 watts.

21. A semiconductor integrated circuit fabricated according to the method of claim 17.

22. A method of fabricating a semiconductor integrated circuit, comprising:
providing a low-k dielectric portion;
reactive ion etching the low-k dielectric portion to produce a feature;
during said reactive ion etching step, providing on the feature a metallic liner material to produce a lined feature; and
depositing copper on the lined feature.

23. A semiconductor integrated circuit fabricated according to the method of claim 22.

24. A method of fabricating a semiconductor integrated circuit, comprising:
providing a low-k dielectric portion;
in an etch chamber, reactive ion etching the low-k dielectric portion to produce a feature;
in said etch chamber, providing on the feature a metallic liner material to produce a lined feature; and
depositing copper on the lined feature.

25. A semiconductor integrated circuit fabricating according to the method of claim 24.
